(19) United States
(12) Patent Application Publication
(10) Pub. No.: US 2026/0065145 A1
(43) Pub. Date: Mar. 5, 2026

(54) TRAINING METHOD

(71) Applicant: Hon Hai Precision Industry Co., Ltd., New Taipei City (TW)

(72) Inventors: Tejender Singh Rawat, New Taipei City (TW); Chia-Lung HUNG, New Taipei City (TW); Wei-Cheng YU, New Taipei City (TW); Yi-Kai HSIAO, New Taipei City (TW)

(73) Assignee: Hon Hai Precision Industry Co., Ltd., New Taipei City (TW)

(21) Appl. No.: 19/059,327

(22) Filed: Feb. 21, 2025

Related U.S. Application Data
(60) Provisional application No. 63/690,318, filed on Sep. 4, 2024.

(51) Int. Cl. G06N 20/00; G06F 30/32

(52) U.S. Cl. CPC G06N 20/00; G06F 30/32

(57) ABSTRACT

A method is used for training a reinforcement learning (RL) model to predict a breakdown voltage (BV) of a semiconductor device with a guard ring. The method comprises determining a set of structural parameters of the semiconductor device; preparing a training dataset formed by a plurality of manufacturing parameters of the semiconductor device, wherein the plurality of manufacturing parameters comprise a dose concentration and at least one dose energy of implanting a guard ring (GR) on the semiconductor device; and training the RL model using the training dataset by maximizing a reward function calculated based on a between a predicted BV value generated by the RL model and a target BV value corresponding to the plurality of manufacturing parameters.

### CROSS-REFERENCE TO RELATED APPLICATION

This application claims priority to U.S. Provisional Application No. 63/690,318 filed on Sep. 4, 2024, of which the entire disclosure is hereby incorporated by reference in its entirety.

### BACKGROUND

### 1. Technical Field

The disclosure generally relates to a method, and more particularly, to a training method.

### 2. Description of Related Art

For high voltage silicon carbide (SiC) vertical double-diffused metal-oxide-semiconductor field effect transistors (VDMOSFET), multiple floating guard rings (FGR) are widely used for their easy implementations on the active area without additional fabrication steps, thereby lowering fabrication costs and manufacturing costs. Usually, characteristics of a guard ring (GR) are affected by manufacturing parameters, for example but not limited to, width, spacing, depth, and doping concentration along with how many GRs are disposed in the same semiconductor device. In some circumstances, increasing the number and width of the guard rings may improve their performances but that acquires larger area on the wafer. With growing attentions have been focused on the prediction and extension of the remaining useful lifetime of SiC power devices, there is still a pressing need for further advancements in the device's GR design to enhance their overall performance and reliability.

Simulating designs using technology computer-aided design (TCAD) and then making improvements is a time-consuming process which delays the overall design process. One possible solution to such issue may be implementing the machine learning (ML) on TCAD data. Recently, ML techniques have been widely integrated with TCAD to mitigate the challenges in terms of simulation runtime and overall process optimization. However, even with the potential of ML to analyze and optimize the device performance, a thorough evaluation to reliability performances of the SiC high-power devices is still hard to achieve.

### SUMMARY

Accordingly, the disclosure is directed to a method for training an RL model capable of evaluating reliabilities of a semiconductor device with at least one guard ring.

A method of the present disclosure is for training a reinforcement learning (RL) model to predict a breakdown voltage (BV) of a semiconductor device with a guard ring. The method comprises determining a set of structural parameters of the semiconductor device; preparing a training dataset formed by a plurality of manufacturing parameters of the semiconductor device, wherein the plurality of manufacturing parameters comprise a dose concentration and at least one dose energy of implanting a guard ring (GR) on the semiconductor device; and training the RL model using the training dataset by maximizing a reward function calculated based on a between a predicted BV value generated by the RL model and a target BV value corresponding to the plurality of manufacturing parameters.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a flowchart of the training method according to some embodiments of the present disclosure.

FIG. 2A illustrates the semiconductor device used in step S10 in accordance with some embodiments of the present disclosure.

FIG. 2B illustrates a training dataset used in step S11 in accordance with some embodiments of the present disclosure.

FIG. 2C illustrates the RL model used in step S12 in accordance with some embodiments of the present disclosure.

FIG. 3 illustrates a relationship curve between the implant concentration and BV in accordance with some embodiments of the present disclosure.

### DESCRIPTION OF THE EMBODIMENTS

In the present disclosure, the single ML model implemented using reinforcement learning (RL) on the high voltage, such as 1.7 kV, SiC GR design is presented. The RL agents will be implemented to process the TCAD-simulated device's data, verifying their reliability. Usually, the BV of a semiconductor device with GR changes rapidly as the structural parameters, therefore, initially, RL agents will be trained to learn a few parameters necessary that determine BV, such as GR implantation dose and energy. This is a useful way to predict the parameters and can be implemented directly on the new device's design and can be confirmed with the TCAD simulation.

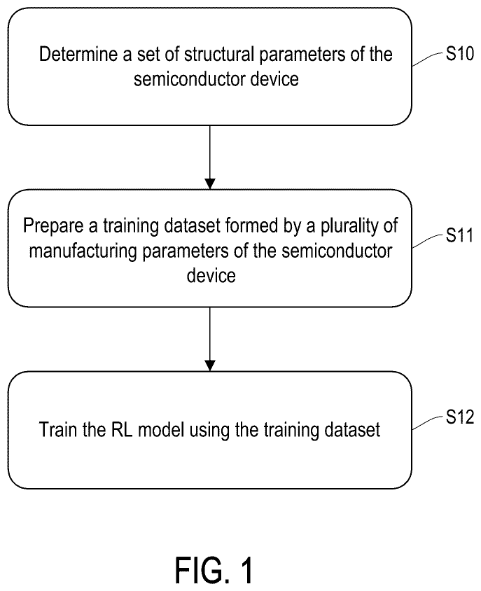

FIG. 1 illustrates a flowchart of the training method according to some embodiments of the present disclosure. As can be seen in FIG. 1, the training method includes steps S10-S12.

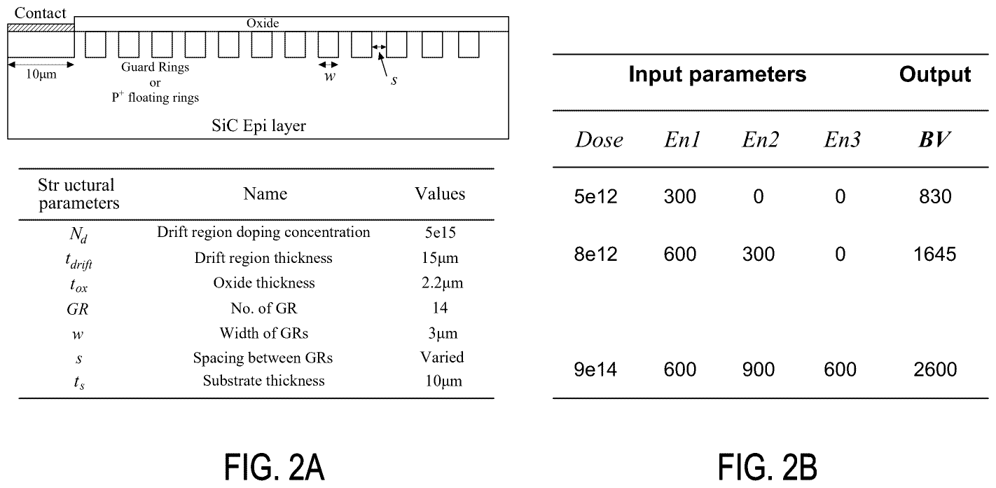

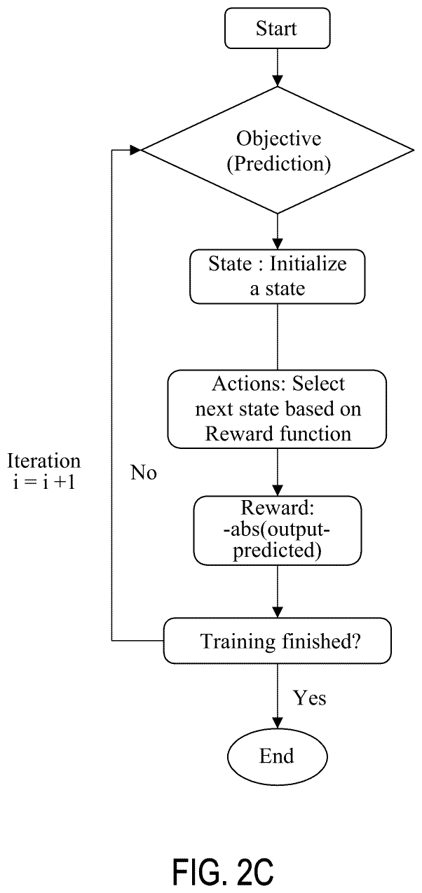

In step S10, parameters of a semiconductor device with at least one GR are setup. FIG. 2A illustrates the semiconductor device used in step S10 in accordance with some embodiments of the present disclosure. In this embodiment, a 2-dimensional 1.7 kV SiC VDMOSFET with a total of 14 GRs has been used. The width (w) of all GRs were fixed at 3 μm and spacing(s) of the GR have been slightly increased as the distance from the active region increases. To accurately calculate the BV in GRs, the hole quasi-Fermi potential is implemented independently for each p+ floating ring or GR. In addition, a coupled solution of both Poisson's equation and current continuity equations are also implemented for accurate results.

TABLE I
Structural parameters of 1.7 kV GR design

| Structural | | | |
|---|---|---|---|
| Parameters | Name | Values | |
| N_{d} | Drift region doping | 5e15 | cm⁻³ |
| | concentration | | |
| t_{drift} | Drift region thickness | 15 | μm |
| Tₒₓ | Oxide thickness | 2.2 | μm |
| GR | No. of GR | 14 | |
| w | Width of GRs | 3 | μm |
| S | Spacing between GRs | Varied | |
| tₛ | Substrate thickness | 10 | μm |

For ML, the implantation dose of the GR has been varied from 5e11 to 9e14 and every single dose has been implanted with either a single energy or in combination of two or three energies. Hence, various scenarios of TCAD have been simulated to generate a dataset for the ML algorithm. For each simulated scenario, the corresponding BV of the device has obtained. The implantation energies used in this experiment are 300, 600, and 900 keV.

In step S11, a training dataset formed by a plurality of manufacturing parameters of the semiconductor is prepared. FIG. 2B illustrates a training dataset used in step S11 in accordance with some embodiments of the present disclosure. The manufacturing parameters includes a dose concentration and at least one dose energy of implanting the guard ring on the semiconductor device. In the present disclosure, a simulation environment of Synopsis Sentaruas TCAD has been used for all simulations, where device structure and electrical parameters were defined and computed using SProcess and SDevice respectively. In some circumstances, GRs are implanted with a various combination of doses and energy which define the depth of the GR. Therefore, the determined dose and energy parameters are inputted to the simulation environment to obtain the corresponding output values of BV.

The dataset for training has been obtained by simulating various scenarios of dose and energies using TCAD. The dataset includes a combination of (dose, energy1), or (dose, energy1, energy2), or (dose, energy1, energy2, energy3), i.e., same dose concentration is implanted with single energy or in combination of 2 or 3 energies, as shown in Table II. The implantation conditions will remain the same for all GRs. Hence, one scenario will produce one BV value. As each implantation dose and energy is independent of the other and has independent effects on the BV of the device, and therefore it makes the environment dynamic and nondeterministic. Therefore, RL has been implemented to validate the reliability.

TABLE II
Various process parameters of dose and energy
for obtaining data points for ML.

| Dose Conc. | Energy 1 | Energy 2 | Energy 3 | Breakdown |
|---|---|---|---|---|
| (cm⁻²) | (keV) | (keV) | (keV) | Voltage (V) |
| 5e11 | 300 | 0 | 0 | 650.632 |
| . . . | | | | . . . |
| 9e14 | 900 | 0 | 0 | 677.18 |
| 5e11 | 300 | 600 | 0 | 661.632 |
| . . . | | | | . . . |
| 9e14 | 300 | 600 | 0 | 692.23 |
| 5e11 | 300 | 600 | 900 | 1704.01 |
| . . . | | | | . . . |
| 9e14 | 300 | 600 | 900 | 2447.65 |

In step S12, the RL model is trained using the training dataset prepared in step S11 by maximizing a reward function calculated based on a between a predicted BV value generated by the RL model and a target BV value corresponding to the plurality of manufacturing parameters. FIG. 2C illustrates the RL model used in step S12 in accordance with some embodiments of the present disclosure. Particularly, the agents have been trained on various combinations of implantation doses with energy, as shown in Table I. In the RL, an agent acquires information through repeated interaction with its environment. With every interaction, the agent gains experience by exploring various action sequences within the defined set of actions (A) and states (S). The RL agent forms a closed loop with its environment, where the agent is rewarded based on the actions (at ε A) taken at state (st ε S). At every step, t, the agent is presented with a new state (st+1) and reward (r) which helps in enhancing the experience. This whole process is repeated to maximize the total rewards from the environment.

This discrete and stochastic nature of the states and actions makes a process a Markov decision process (MDP). In MDP, the agent's goal is to learn a mapping of states to action, and hence optimize the policy (π*). Therefore, by providing feedback as a reward to an agent, RL ensures the agent's learning processes are in the right direction. This can be expressed mathematically:

$${π}^{*} = arg {max}_{π} E [ {\sum }_{t = 0}^{T} {γ}^{t} R ( {S}_{t} , {a}_{t} ) ]$$

where T is the length of the episode, R is the reward function at time t and γε(0, 1) is the discount factor.

For training, the advantage actor-critic (A2C) and proximal policy optimization (PPO) agents have been used using the tensorforce library. RL agents are classified either as value-based or policy-based agents. A2C is a model-free agent that uses a hybrid architecture where the actor controls the agent's behavior by optimizing the policy, i.e., policy-based, and the critic controls the effectiveness of the agent's action by estimating the total reward, i.e., value-based. This hybrid architecture stabilizes the training by reducing the variance. The advantage value, A(st, at), in A2C defines whether the agent's action is better as compared to the average action at the given state, and is defined as: A(st, at)=Q(st, at)−V(st), where V(s) is a value function and Q(s, a) is an action value function. PPO, as the name suggests, is a model-free policy-based RL agent that focuses on optimizing its policy by updating its current policy using a small step size and hence provides stability during training. PPO also implements an actor-critic method to optimize its learning.

For baseline comparison, given the regression nature of the input-output relationship and limited dataset size, the eXtreme Gradient Boosting (XGBoost) regression model for comparison is adopted. XGBoost is a powerful gradient-boosting algorithm based on decision trees, renowned for its exceptional prediction accuracy and efficiency. It sequentially trains an ensemble of weak learners, typically decision trees, thus creating a strong predictive model. Moreover, XGBoost handles missing data robustly, is resistant to overfitting, and offers flexibility in model tuning through parameters such as tree depth, learning rate, and regularization, ensuring optimal performance. In contrast to the regression model, multiple output values are required and therefore XGBoost with a Tree-structured Parzen Estimator (TPE) are integrated. TPE is a hyperparameter optimization method based on a sequential model-based optimization (SMBO) approach.

The problem of mapping independent parameters to the BV of the device is formulated using the tensorforce library for RL. This scenario of optimizing the parameters (Op) can be formulated as an MDP problem and can be represented as Op=[S, A, P, R], where S denotes the set of all possible states available in the environment (st ε S), A denotes the set of all possible actions that can be taken by the agent to maximize its reward (at ε A), P denotes probability between two states, and R denotes the accumulation of all rewards, respectively. The pseudo-algorithm of the RL agent is shown in Table III.

TABLE III
Algorithm for BV prediction using RL agents.

```
1. Define environment: Custom Environment( )
    Environment: CSV Dataset
    States: s = (Dose, En1, En2, En3), shape = (4,)
    Action: a = learn each parameter for BV
    Reward: r = -abs(output − target)
    Execute: for every timestep, calculate:
      next_state, terminal, reward
2. Define Agents: A2C and PPO
3. Start training
    for epochs = 1→maximum iteration
      observe state space
      execute actions for each state
      calculate rewards
    end
4. return trained RL model
```

For the RL agent to learn the importance of all input parameters independently on the BV of the device, we have to explicitly define the parameters of MDP for an agent using the tensorforce library as follows.

State space: The state space includes all the input parameters that the agent will observe or learn. Therefore, the dataset will be the state space, except for the BV values. Hence, state space will look like this, S=[D, En1, En2, En3], where D represents the dose of the implantation, and En1, En2, and En3 represent the implantation energy for that particular dose. Here, En1, En2, and En3 can individually take any value from (0, 300, 600, 900) keV. For example, if any dose is implanted using single energy only, then that dose will have only En1 and other energies will be marked as 0, i.e., En1=300 or 600 or 900, En2=0, En3=0. Similarly, if any dose is implanted using two energies, then En3 will be marked as 0.

Action space: The action space defines the possible actions that can be taken by the agent for every state space. Here, the actions of the agent will be to choose values of dose and energies, respectively, and independently. For dose, a range is defined i.e., 5e11 to 9e14 cm-2, and hence action will be choosing any value between that range. Similarly, for En1. En2, and En3, actions will choose any value from (0, 300, 600, and 900) for each energy independently.

Reward: This function defines the learning of the agent, and therefore it is very important to define it clearly and precisely. This situation becomes complex as it is desirable for the agent to learn the dependence of each parameter on the BV of the device, and thus it becomes very difficult to define the reward for an agent. Thus, the reward function R(st, at) for a specific state and action at timestep t is defined as a negative absolute difference between the output and target BV value.

Based on the data generated from TCAD simulations, a metamodel will be constructed to predict the mathematical relationship between input parameters and output responses. In the present disclosure, XGBoost is used to construct the metamodel because of the regression nature of the dataset. For relevant comparison, the regression model is integrated with the optimization algorithm, as they iteratively explore the solution space to minimize or maximize the objective function. For this reason, the TPE is selected as the optimization algorithm due to its efficient modeling of the objective function's probability distribution and effective guidance of parameter exploration toward promising regions.

In the experimental setup, crucial aspects related to the training of the metamodel and the optimization process are defined. The pseudo algorithm is shown in Table IV. For XGBoost regression with regularization, the loss function incorporates both the mean squared error (MSE) term for model fitting and an additional regularization term to prevent overfitting. The modified loss function can be represented as:

$$Loss = \frac{1}{N} {\sum }_{i = 1}^{N} {( {y}_{i} - \hat{{y}_{ι}} )}^{2} + {\sum }_{j = 1}^{J} Ω ( {δ}_{j} )$$

$$Ω ( δ ) = α \vert δ \vert + \frac{1}{2} β {‖ ω ‖}^{2}$$

where N is the number of data points, yi denotes the actual output for the i-th data point, ŷi represents the predicted output for the i-th data point, J denotes the number of trees in the model, Ω denotes the regularization term applied to each tree to penalize the complexity of the model, β denotes the L2 norm coefficient and α denotes L1 norm coefficient. |δ| denotes the number of leaves of tree δ, and ω denotes the vector of values attributed to each leaf.

TABLE IV
Algorithm for BV prediction using XGBoost and TPE.

```
1. Train a metamodel using XGBoost:
    Input: dose, energy 1, energy 2, energy 3
    Define loss function: Mean Square Error (MSE)
    Train regression model with XGBoost
    Output: Predicted BV
2. Single objective optimization using TPE:
    Objective function: Predicted BV from metamodel
    Search space:
      Dose: [5e11, 5.5e11, ..., 9e14]
      Energy1: [300, 600, 900, 0]
      Energy2: [300, 600, 900, 0]
      Energy3: [300, 600, 900, 0]
    Start search:
      Initialize score → − ∞
      Initialize input_parameters → None
      for timestep → maximum search time
      select input_parameters
      predict BV
      if predicted BV > score
        score = predicted BV
        input_parameters = current input_parameters
    end
    return score and input_parameters
```

The dataset of the device's BV TCAD results is defined as the environment for the RL agent to observe, act, and build its learning based on its policy. By continuously interacting with the environment, the agent will be rewarded based on the action taken in every state it will encounter. Every new state an agent will observe is based on the agent's action and for every action it will gain reward from the environment. The agent's objective is to maximize its reward function and hence improve the agent's learning. In training, the agent will always observe a set of states as, s=(Dose, En1, En2, En3, BV). Here, the agent will learn the effects of dose and energy combination on the BV value of the device.

For training, advantage actor-critic (A2C) and proximal policy optimization (PPO) agents are selected. Both agents were trained to interact with a custom environment designed to simulate under various conditions. Agent's performance was evaluated over 1000 episodes, with each episode representing the interaction of the agent with the environment. The agent's actions were influenced by the state of the environment, which was dynamically generated from the dataset containing simulated TCAD data of the device BV values. The agents were trained using an “auto” network architecture consisting of 3 dense layers with 128 neurons in each layer. Some parameters that were defined for both agents are as follows: a memory size of 2000, a batch size of 5 and 10, an exploration rate of 0.2 and 0.4, and a learning rate of 1e-3. The discount factor was set to 0.99, indicating the importance of future rewards in the decision-making process.

Throughout the training process, the agent's performance was monitored by tracking the cumulative rewards obtained in each episode. This metric is crucial for assessing the agent's ability to learn the optimal policy for interacting with the environment. The results showed a significant improvement in the agent's performance throughout the training episodes, indicating that the agent was able to adapt to the changing conditions of the environment and improve its policy over time.

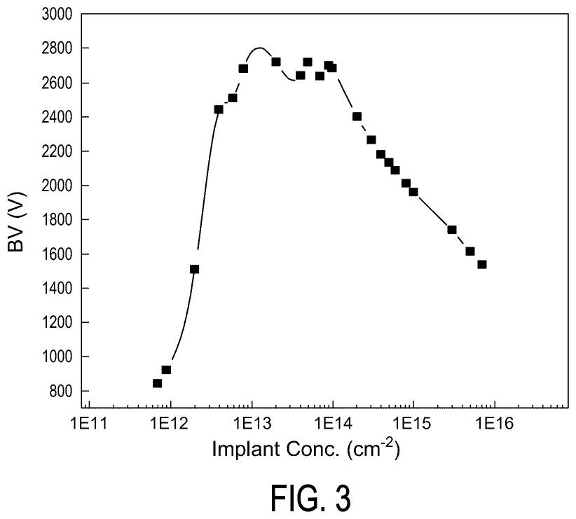

FIG. 3 illustrates a relationship curve between the implant concentration and BV in accordance with some embodiments of the present disclosure. It can be observed in FIG. 3 that the 1.7 kV device's maximum BV value is slightly above 2.7 kV, and both RL agents have observed the parameters required for that particular BV. Therefore, the trained RL agents are tested to predict the parameters for the targeted output value of the 2.5 kV design. The parameter values hence obtained from the trained RL agents, were verified using the TCAD simulations. The results obtained using RL agents with their respective hyperparameters are shown in Table V.

Comparatively, both agents were successful in predicting the parameters for the 2.5 kV GR design, but the PPO agent is more efficient when it comes to predicting values for the 2.5 kV design. Relatively, the A2C agent is more efficient when it comes to exploring the observation space, as it has predicted almost all input parameter values. After training, the parameters predicted by the RL agent for the 2.5 kV GR design were implemented in the initial 1.7 kV GR design. The BV values for each prediction are then verified using the TCAD simulation. The last column of Table V, i.e., simulated output, represents the BV values obtained from the TCAD simulations. Out of all these, the BV and electric field distribution of two devices simulated with 2 and 3 energies are shown in FIG. 4.

TABLE V
RL agents, hyperparameters, and the result obtained after training.

| | | | | Input Parameters | | | | |
|---|---|---|---|---|---|---|---|---|
| Target | | Batch | | Dose | En1 | En2 | En3 | Simulated |
| BV | Agent | Size | Exploration | (×10¹⁴ cm⁻²) | (keV) | (keV) | (keV) | BV |
| 2500 V | PPO | 5 | 0.2 | 4.489 | 300 | 600 | 600 | 2671.229 |
| | PPO | 10 | | 4.542 | 900 | 900 | 0 | 2057.394 |
| | PPO | 5 | 0.4 | 4.492 | 300 | 0 | 600 | 2638.773 |
| | PPO | 10 | | 4.531 | 600 | 0 | 600 | 2690.582 |
| | A2C | 5 | 0.2 | 4.491 | 600 | 0 | 300 | 2650.535 |
| | A2C | 10 | | 4.503 | 900 | 900 | 900 | 1946.295 |
| | A2C | 5 | 0.4 | 4.5 | 900 | 300 | 300 | 2228.084 |
| | A2C | 10 | | 4.499 | 600 | 300 | 300 | 2732.704 |

TCAD-simulated datasets are utilized to train a regression model aimed at predicting the BV. The model's input features consist of various combinations of dose and energies, with BV being the output variable. Employing XGBoost as the meta-model forms the backbone of the framework. Next, the TPE is used, a Bayesian optimization algorithm adept at scenarios involving meta-model-based optimization. Its capacity to leverage the predictive abilities of the meta-model to guide the search process makes it particularly suitable for global optimization tasks.

Initially, the dataset is augmented from 70 to 255 to ensure efficient training of the model. For the training set, 60% of the available data is utilized to train the metamodel. For this experiment, the learning rate is set to 0.3, max depth is set to 15, the number of estimators is set to 38, α is set to 0.028 and β is set to 0.484. Additionally, a maximum search time is set to 50 for optimization, defining the duration within which the optimization algorithm explores the solution space to identify the optimal solution.

Notably, through 50 iterations, the optimization algorithm identifies the optimal breakdown point at 2781 Volts, corresponding to input parameters dose=9e13 and energies=(0, 600, 300), as shown in Table VI. Subsequently, the simulated breakdown voltage is validated through comparison with TCAD simulations. Here, timesteps define the number of iterations, the model has taken to identify the maximum BV using all the available search space for dose and energies. Even though TPE has determined the maximum BV of 2781 using only 10 iterations or timesteps, the TPE model is still allowed to complete its 50 timesteps. This highlights the exploring capability of TPE in the same way as RL agents. Here, it can be seen that even in exploration, the TPE model's predicted BVs are almost in the same range.

TABLE VI
Meta-model result.

| | | | Predicted | Simulated |
|---|---|---|---|---|
| Timestep | Dose | Energies | BV | BV |
| 10 | 9E+13 | (0, 600, 300) | 2781.233 | 2632.749 |
| 16 | 5E+13 | (0, 600, 600) | 2779.339 | 2636.993 |
| 46 | 5E+14 | (0, 300, 300) | 2769.143 | 2628.978 |
| 29 | 9E+13 | (900, 600, 300) | 2745.69 | 2713.32 |
| 34 | 9B+13 | (0, 600, 0) | 2737.071 | 2632.749 |

Again, the predicted parameters of the TPE model have been confirmed using the TCAD simulations, as shown in the last column of Table VI. Simulation results confirm that the TPE model predictions are very close to actual results, hence highlighting the efficiency of the model.

While comparing the performance of RL with the meta-model-based optimization method, several observations were made from the experimental results. Firstly, the RL method requires setting up a target value, while the metamodel-based optimization method doesn't require additional target setting. RL method's objective is to understand the dependence of parameters individually on the BV, whereas the meta-model's objective is to maximize the output values as much as possible. This reflects the difference in target setting between the two methods, where RL emphasizes reaching specific goals, while the meta-model-based optimization method focuses more on optimizing output values. Secondly, differences were observed in the recommended results. The recommended dose by RL falls within a larger range, potentially due to the effect of the limited dataset on the agent's learning that a larger dose may yield large BV values. As a result, as demonstrated above, the trained metamodel may be used to validate whether the predicted BV meet the requirements, so that the manufacturing parameters corresponding to the validated BV may be used for fabricating the semiconductor device, thereby shortening cycle time of designing the semiconductor device with GRs.

In conclusion, the present disclosure highlights the important fact that even in the limited dataset, RL's efficiency in predicting the parameters is commendable. In addition, with RL more options become available to improve the efficiency by tuning the various hyperparameters accordingly. Furthermore, RL's ability to continuously learn and adapt according to the dynamic and stochastic environment over time and hence can be implemented directly to optimize semiconductor processes in real-world environments. Alternatively, meta-model regression-based training requires a sufficient amount of training data for efficient training. Even though the meta-model-based optimization method is relatively simpler and more feasible, especially subjected to the large amount of data available for training. However, this method relies on the accuracy of the meta-model, which directly affects the final optimization results. In addition, the main factor for selecting the meta-model method as the comparative model against RL is that both of these exploit exploration and exploitation for the search and learning, respectively. In addition, both of these are well suited for high-dimension spaces.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method for training a reinforcement learning (RL) model to predict a breakdown voltage (BV) of a semiconductor device with a guard ring, the method comprising:
determining a set of structural parameters of the semiconductor device;
preparing a training dataset formed by a plurality of manufacturing parameters of the semiconductor device, wherein the plurality of manufacturing parameters comprise a dose concentration and at least one dose energy of implanting a guard ring (GR) on the semiconductor device; and
training the RL model using the training dataset by maximizing a reward function calculated based on a between a predicted BV value generated by the RL model and a target BV value corresponding to the plurality of manufacturing parameters.

2. The method of claim 1, wherein the RL model uses an extreme Gradient Boosting (XGBoost) regression model for comparison.

3. The method of claim 2, wherein the RL model is a metamodel integrating the XGBoost model with a Tree-structured Parzen Estimator (TPE).

4. The method of claim 3, wherein the TPE is selected as an optimization algorithm.

5. The method of claim 1, wherein a reward function of the RL model is expressed as:
$$r = - \vert output - target \vert$$
wherein r is a reward value, output is the predicted BV value, and target is the target BV value.

6. The method of claim 5, wherein advantage actor-critic (A2C) and proximal policy optimization (PPO) agents are deployed for training the RL model.

7. The method of claim 6, wherein performance of the agents is monitored by tracking a cumulative reward obtained in each episode.

8. The method of claim 7, wherein the agent's objective is to maximize the cumulative reward.

9. The method of claim 6, wherein the agents are trained using an auto network architecture consisting of 3 dense layers with 128 neurons in each of the dense layer.

10. The method of claim 1, wherein a loss function of the RL model is expressed as:
$$Loss = \frac{1}{N} {\sum }_{i = 1}^{N} {( {y}_{i} - \hat{{y}_{ι}} )}^{2} + {\sum }_{j = 1}^{J} Ω ( {δ}_{j} )$$
$$Ω ( δ ) = α \vert δ \vert + \frac{1}{2} β {‖ ω ‖}^{2}$$
wherein N is a number of data points, yi denotes an actual output for an i-th data point, ŷi represents a predicted output for the i-th data point, J denotes a number of trees in the RL model, Ω denotes a regularization term applied to each tree to penalize a complexity of the RL model, β denotes a L2 norm coefficient and α denotes L1 norm coefficient, |δ| denotes a number of leaves of the tree δ, and ω denotes a vector of values attributed to each leaf.
